(19) United States
(12) Patent Application Publication
(10) Pub. No.: US 2016/0176169 A1
(43) Pub. Date: Jun. 23, 2016

(54) Protective Film Formation-Use Composite Sheet

(71) Applicant: LINTEC CORPORATION, Tokyo (JP)

(72) Inventors: Hiroyuki Yoneyama, Nagareyama-shi (JP); Naoya Saiki, Koshigaya-shi (JP)

(21) Appl. No.: 14/907,538

(22) PCT Filed: Jul. 16, 2014
(86) PCT No.: PCT/JP2014/068894

§ 371 Date: Jan. 25, 2016

(30) Foreign Application Priority Data
Aug. 1, 2013 (JP) 2013-160384

(51) Int. Cl. B32B 27/32; H01L 21/683; C09J 7/02; B32B 7/12; B32B 27/08

(52) U.S. Cl. CPC B32B 27/32; B32B 7/12; B32B 27/08; C09J 7/0275; H01L 21/6836; B32B 2457/14; C09J 2423/106; C09J 2201/122; C09J 2203/326; H01L 2221/68327; H01L 2221/6834; H01L 2221/68377

(57) ABSTRACT

A composite sheet (1) for forming a protective film, including an adhesive sheet (2) formed by laminating an adhesive layer (22) on one surface of a base material (21), and a protective-film forming film (3) laminated on the adhesive layer (22) side of the adhesive sheet (2), wherein the adhesive sheet (2) does not have a through hole penetrating through the adhesive sheet (2) in the thickness direction, and the light transmittance of the adhesive sheet (2) at a wavelength of 532 nm which is measured using an integrating sphere is from 75 to 85%.

According to this composite sheet (1) for forming a protective film, while using an adhesive sheet having no through holes, it is still possible to suppress the generation of a gas reservoir between the adhesive sheet and the protective-film forming film (protective film) when laser printing is performed on the protective-film forming film (protective film).

### TECHNICAL FIELD

The present invention relates to a composite sheet for forming a protective film (protective-film forming composite sheet) which is adhered to a workpiece such as a semiconductor wafer so that the workpiece can be subjected to processing (for example, dicing) in that state, and which is capable of forming a protective film for the workpiece or a product obtained by processing the workpiece (for example, a semiconductor chip).

### BACKGROUND ART

In recent years, a semiconductor device has been manufactured by a mounting method called a face-down method. In this method, at the time of mounting a semiconductor chip having a circuit surface on which electrodes such as bumps have been formed, the circuit surface side of the semiconductor chip is bonded to a chip mounting portion such as a lead frame. Therefore, a structure is obtained in which the back surface side of the semiconductor chip where no circuit has been formed is exposed.

For this reason, in order to protect the semiconductor chip, a protective film constituted of a hard organic material is often formed on the back surface side of the semiconductor chip. Printing is usually conducted on the protective film in order to display the product number or the like of the semiconductor chip. As the printing method, a laser marking method (laser printing) for irradiating a laser beam to the protective film has been generally employed.

Here, Patent Documents 1 to 3 have disclosed a sheet that integrates the protective film formation and dicing in which a protective-film forming layer (protective-film forming film) capable of forming the above-mentioned protective film has been formed on an adhesive sheet. According to this sheet that integrates the protective film formation and dicing, both the dicing of a semiconductor wafer and the protective film formation on a semiconductor chip can be performed, which makes it possible to obtain a semiconductor chip with a protective film.

More specifically, the sheet that integrates the protective film formation and dicing is attached to the semiconductor wafer, and the protective-film forming layer is cured by heating to form a protective film. Thereafter, the protective film was subjected to laser printing through the adhesive sheet and diced into individual pieces of chip. Here, when performing the laser printing, the gas due to deterioration (mainly combustion) of the protective film may accumulate between the adhesive sheet and the protective film. When a gas reservoir is generated as described above, the visibility of the printing deteriorates, which makes an individual recognition of the chip impossible at times. In addition, there is also a possibility that adhesion between the adhesive sheet and the protective film becomes insufficient, and the semiconductor chip may come off from the adhesive sheet during the dicing step.

Accordingly, in Patent Document 4, by providing a through hole in the adhesive sheet in advance, an adhesive sheet for wafer processing has been proposed, which is configured so as to remove the gas generated by laser printing from the through hole.

### CITATION LIST

### Patent Documents

[Patent Document 1] Japanese Unexamined Patent Application, First Publication No. 2006-140348

[Patent Document 2] Japanese Unexamined Patent Application, First Publication No. 2012-33637

[Patent Document 3] Japanese Unexamined Patent Application, First Publication No. 2011-151362

[Patent Document 4] Japanese Unexamined Patent Application, First Publication No. 2012-169441

### SUMMARY OF INVENTION

### Technical Problem

However, in the adhesive sheet for wafer processing in Patent Document 4, in the case of performing laser printing between the through holes, degassing from the through holes is not possible at times, thereby generating a gas reservoir.

The present invention has been made in view of the above circumstances, and has an object, while using an adhesive sheet having no through holes, of providing a composite sheet for forming a protective film that can suppress the generation of a gas reservoir between the adhesive sheet and a protective-film forming film (protective film) when laser printing is performed on the protective-film forming film (protective film).

### Solution to Problem

In order to achieve the above object, the present invention firstly provides a composite sheet for forming a protective film (protective-film forming composite sheet), the composite sheet including an adhesive sheet obtained by laminating an adhesive layer on one surface of a base material, and a protective-film forming film laminated on the aforementioned adhesive layer side of the aforementioned adhesive sheet, characterized in that the aforementioned adhesive sheet does not have a through hole penetrating the adhesive sheet in the thickness direction, and the light transmittance of the aforementioned adhesive sheet at a wavelength of 532 nm which is measured using an integrating sphere is from 75 to 85% (Invention 1).

When a laser beam is irradiated from the adhesive sheet side onto the protective-film forming composite sheet according to the above invention (Invention 1), the material of the laser-beam irradiated portion in the adhesive sheet having the above-mentioned light transmittance is decomposed and evaporated, thereby forming a pore that penetrates the adhesive sheet. As a result, even if a gas is generated from the protective-film forming film (protective film) by laser printing, since the gas is removed through the pore, generation of the gas reservoir between the adhesive sheet and the protective-film forming film (protective film) can be effectively suppressed. In addition, since the above adhesive sheet transmits visible light to some extent, the above protective-film forming composite sheet exhibits excellent printing visibility via the adhesive sheet.

In the above invention (Invention 1), at least a portion in the aforementioned adhesive layer which is in contact with the aforementioned protective-film forming film is preferably constituted of a material obtained by curing an energy ray-curable adhesive (Invention 2).

In the above inventions (Inventions 1 and 2), the aforementioned base material is preferably constituted of a polypropylene film (Invention 3).

In the above inventions (Inventions 1 to 3), it is preferable that the aforementioned protective-film forming film is constituted of an uncured curable adhesive, and a surface gloss value on the aforementioned adhesive layer side of the aforementioned protective-film forming film after curing is equal to or more than 25 (Invention 4).

In the above inventions (Inventions 1 to 4), it is preferable that an object to which the aforementioned protective-film forming composite sheet is adhered is a semiconductor wafer, and the aforementioned protective-film forming film is a layer for forming a protective film onto the aforementioned semiconductor wafer or a semiconductor chip obtained by dicing the aforementioned semiconductor wafer (Invention 5).

### Advantageous Effects of Invention

According to the protective-film forming composite sheet of the present invention, while using an adhesive sheet having no through holes, it is still possible to suppress the generation of a gas reservoir between the adhesive sheet and the protective-film forming film (protective film) when laser printing is performed on the protective-film forming film (protective film). In addition, the protective-film forming composite sheet according to the present invention exhibits excellent printing visibility via the adhesive sheet.

### BRIEF DESCRIPTION OF DRAWINGS

FIG. 1 is a cross sectional view of a composite sheet for forming a protective film (protective-film forming composite sheet) according to an embodiment of the present invention.

FIG. 2 is a cross sectional view of the protective-film forming composite sheet according to another embodiment of the present invention.

FIG. 3 is a cross sectional view of the protective-film forming composite sheet according to another embodiment of the present invention.

FIG. 4 is a cross sectional view showing an example of using a protective-film forming composite sheet according to an embodiment of the present invention.

FIG. 5 is a plan view of a protective-film forming composite sheet prepared in an example.

### DESCRIPTION OF EMBODIMENTS

An embodiment of the present invention will be described below.

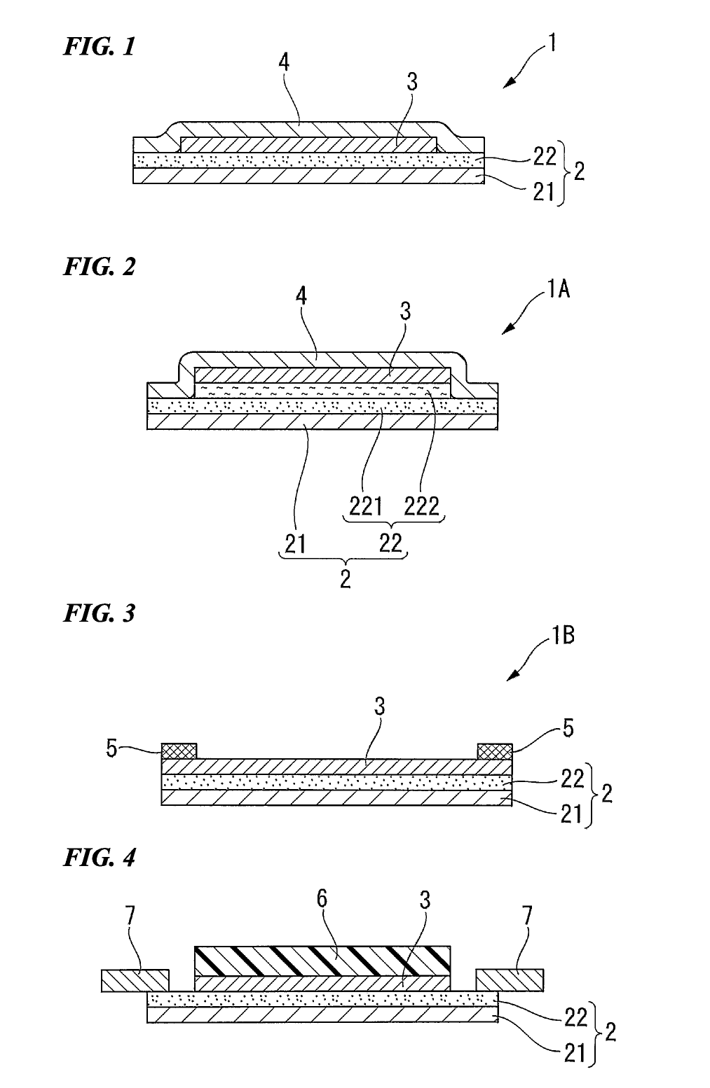

FIG. 1 is a cross sectional view of a composite sheet for forming a protective film (protective-film forming composite sheet) according to an embodiment of the present invention. As shown in FIG. 1, a protective-film forming composite sheet 1 according to the present embodiment is configured to include an adhesive sheet 2 formed by laminating an adhesive layer 22 on one surface of a base material 21, a protective-film forming film 3 laminated on the adhesive layer 22 side of the adhesive sheet 2, and a release sheet 4 laminated on the opposite side of the adhesive sheet 2 in the protective-film forming film 3. However, the release sheet 4 is peeled off when using the protective-film forming composite sheet 1.

The protective-film forming film 3 in the embodiment is formed so as to be approximately the same size as the workpiece in the surface direction or slightly larger than the workpiece, and also to be smaller than the adhesive sheet 2 in the surface direction. The release sheet 4 is laminated on the adhesive layer 22 in the portion where the protective-film forming film 3 is not laminated, and it is configured in such a manner that the adhesive layer 22 which is exposed by separating the release sheet 4 can be attached to a jig such as a ring frame.

The protective-film forming composite sheet 1 according to the embodiment is used, when processing a workpiece, in order to hold the workpiece by being attached to the workpiece, as well as to form a protective film for the workpiece or a chip obtained from the workpiece. The protective film is configured from the protective-film forming film 3, and preferably the cured protective-film forming film 3. As an example, it is used in order to hold a semiconductor wafer during the dicing process of the semiconductor wafer serving as a workpiece, as well as to form a protective film to a semiconductor chip obtained by dicing, but the use is not limited thereto.

### 1. Physical Property

The protective-film forming composite sheet 1 according to the embodiment requires that the light transmittance of the adhesive sheet 2 at a wavelength of 532 nm is from 75 to 85%. It should be noted that the term “light transmittance” used in the present description refers to a value measured using an integrating sphere, and a spectrophotometer is used as a measurement instrument.

In those cases where the wavelength of the laser beam used for laser printing which is performed on the protective-film forming film 3 (protective film) is 532 nm, if the light transmittance of the adhesive sheet 2 at the above wavelength is from 75 to 85%, when a laser beam having the above wavelength is irradiated onto the adhesive sheet 2, a relatively large amount of energy of the laser beam is absorbed in the adhesive sheet 2. As a result, the material of the laser-beam irradiated portion in the adhesive sheet 2 is decomposed and evaporated, thereby forming a pore that penetrates the adhesive sheet 2. Therefore, even if a gas is generated from the protective-film forming film 3 (protective film) by laser printing, since the gas is removed through the pore, generation of the gas reservoir between the adhesive sheet 2 and the protective-film forming film 3 (protective film) can be effectively suppressed. Moreover, because the portion of the protective-film forming film 3 (protective film) from which the gas is generated is the laser-beam irradiated portion, that is, a portion where the pore is formed in the adhesive sheet 2, the generated gas is removed from the pore with a high probability. By suppressing the generation of the gas reservoir in this manner, the visibility of the print formed in the protective-film forming film 3 becomes favorable, and the adhesion between the adhesive sheet 2 and the protective-film forming film 3 (protective film) is also secured, so as to enable suppression of the detachment of chips from the adhesive sheet 2 during the dicing step.

Here, the print formed in the protective-film forming film 3 (protective film) will be visually recognized through the adhesive sheet 2. Because the wavelength of visible light is generally from 380 to 780 nm, the adhesive sheet 2 exhibiting a light transmittance of 75 to 85% at a wavelength of 532 nm which is within the range transmits visible light to some extent. Accordingly, the adhesive sheet 2 has a transparency that allows easy visual recognition of the print formed in the protective-film forming film 3 (protective film), and the protective-film forming composite sheet 1 according to the embodiment exhibits excellent printing visibility via the adhesive sheet 2.

If the light transmittance of the adhesive sheet 2 at the above wavelength is less than 75%, the print formed on the protective-film forming film 3 (protective film) may become difficult to see by being blocked by the adhesive sheet 2. On the other hand, if the light transmittance of the adhesive sheet 2 at the above wavelength is more than 85%, the material of the adhesive sheet 2 is hardly decomposed or evaporated, and the pores as described above are not formed. From the viewpoints of the printing visibility of the protective-film forming film 3 and the pore formation in the adhesive sheet 2, the light transmittance of the adhesive sheet 2 at the above wavelength is preferably from 75 to 83%.

The light transmittance of the protective-film forming film 3 is not particularly limited as long as the range allows satisfactory printing by the laser beam irradiation. Normally, when the wavelength of the laser beam used for laser printing which is performed on the protective-film forming film 3 (protective film) is 532 nm, the light transmittance of the protective-film forming film 3 at a wavelength of 532 nm is preferably equal to or less than 20%. In order to improve the moisture resistance while maintaining the hardness of the protective film after curing at a high level, in the protective-film forming film 3, it is common to include a large amount of inorganic materials (for example, inorganic fillers such as silica and inorganic pigments such as carbon black). If the light transmittance of the protective-film forming film 3 at the above wavelength is equal to or less than 20%, when a laser beam having the above wavelength is irradiated onto the protective-film forming film 3 (protective film), the amount of the laser light energy absorbed in the protective-film forming film 3 (protective film) will become very large. However, because the above-mentioned inorganic materials are hardly decomposed or evaporated, the material of the laser-beam irradiated portion in the protective-film forming film 3 (protective film) changes color due to deterioration without forming pores, so as to be subjected to printing.

From the viewpoint of the laser printing properties of the protective-film forming film 3, the light transmittance of the protective-film forming film 3 at the above wavelength is preferably equal to or less than 20% as described above, more preferably equal to or less than 15%, and still more preferably equal to or less than 10%.

### 2. Adhesive Sheet

The adhesive sheet 2 of the protective-film forming composite sheet 1 according to the present embodiment is configured to include a base material 21 and an adhesive layer 22 laminated on one surface of the base material 21. In order to provide the adhesive sheet 2 with the light transmittance as described above, the base material 21 and/or the adhesive layer 22 may be colored, a colored sheet may be provided separately, or both of these configurations may be employed. However, when considering the production cost, it is preferable to color the base material 21 and/or the adhesive layer 22, and also in consideration of the adverse effect on the adhesive force of the adhesive layer 22, it is preferable to color the base material 21.

It should be noted that the adhesive sheet 2 in the present embodiment does not have a through hole that penetrates the adhesive sheet 2 in the thickness direction before using the protective-film forming composite sheet 1.

### 2-1. Base Material

As long as the base material 21 of the adhesive sheet 2 is suitable for processing of the workpiece, for example, dicing and expanding of the semiconductor wafer, and also the pores described above can be formed thereto by the laser beam irradiation, the constituent material thereof is not particularly limited, and it is usually constituted of a film which is mainly composed of a resin-based material (hereinafter, referred to as a “resin film”).

Specific examples of the resin film include polyolefin-based films such as a polyethylene film including a low density polyethylene (LDPE) film, a linear low density polyethylene (LLDPE) film and a high density polyethylene (HDPE) film, a polypropylene film, a polybutene film, a polybutadiene film, a polymethylpentene film, an ethylene-norbornene copolymer film and a norbornene resin film; ethylene-based copolymer films such as an ethylene-vinyl acetate copolymer film, an ethylene-(meth)acrylic acid copolymer film and an ethylene-(meth)acrylate copolymer film; polyvinyl chloride-based films such as a polyvinyl chloride film and a vinyl chloride copolymer film; polyester-based films such as a polyethylene terephthalate film and a polybutylene terephthalate film; a polyurethane film; a polyimide film; a polystyrene film; a polycarbonate film; and a fluorine resin film. In addition, modified films such as cross-linked films and ionomer films of these are also used. The above base material 21 may be a film composed of one type of these, or may be a laminated film obtained by combining two or more types of these. It should be noted that the term “(meth)acrylic acid” in the present description means both acrylic acid and methacrylic acid. The same applies to other similar terms.

Among those described above, in view of the pore formation due to the laser beam irradiation, environmental safety, cost and the like, polyolefin-based films are preferred, and among them, a polypropylene film excellent in heat resistance is preferred. If a polypropylene film is used, it is possible to impart heat resistance to the base material 21 without impairing the expansion suitability of the adhesive sheet 2 and the pick-up suitability of a chip. By providing the base material 21 with such heat resistance, even when the protective-film forming film 3 is thermally cured in a state where the protective-film forming composite sheet 1 is attached to the workpiece, it is possible to suppress the occurrence of loosening of the adhesive sheet 2.

For the purpose of improving the adhesion with the adhesive layer 22 laminated on the surface, if desired, one or both sides of the above resin film can be subjected to a surface treatment by an oxidation method, a roughening method or the like, or to a primer treatment. Examples of the above oxidation method include a corona discharge treatment, a plasma discharge treatment, a chromium oxidation treatment (wet), a flame treatment, a hot air treatment, an ozone treatment, and an ultraviolet irradiation treatment. In addition, as the roughening method, for example, a sand blasting method, a thermal spraying treatment method, and the like can be mentioned.

When coloring the base material 21 in order to impart the light transmittance as described earlier to the adhesive sheet 2, the base material 21 preferably contains a coloring agent in the above resin film. As the coloring agent, it is possible to use known agents, such as inorganic pigments, organic pigments and organic dyes, although it is preferable to use an organic pigment or an organic dye in view of the formation of pores by the laser beam irradiation.

Examples of the inorganic pigments include carbon black, cobalt-based pigments, iron-based pigments, chromium-based pigments, titanium-based pigments, vanadium-based pigments, zirconium-based pigments, molybdenum-based pigments, ruthenium-based pigments, platinum-based pigments, ITO (indium tin oxide)-based pigments, and ATO (antimony tin oxide)-based pigments.

As the organic pigments and organic dyes, for example, aminium-based pigments, cyanine-based pigments, merocyanine-based pigments, croconium-based pigments, squarylium-based pigments, azulenium-based pigments, polymethine-based pigments, naphthoquinone-based pigments, pyrylium-based pigments, phthalocyanine-based pigments, naphthalocyanine-based pigments, naphtholactam-based pigments, azo-based pigments, condensed azo-based pigments, indigo-based pigments, perinone-based pigments, perylene-based pigments, dioxazine-based pigments, quinacridone-based pigments, isoindolinone-based pigments, quinophthalone-based pigments, pyrrole-based pigments, thioindigo-based pigments, metal complex-based pigments (metal complex salt dyes), dithiol metal complex-based pigments, indole phenol-based pigments, triallylmethane-based pigments, anthraquinone-based pigments, dioxazine-based pigments, naphthol-based pigments, azomethine-based pigments, benzimidazolone-based pigments, pyranthrone-based pigments, threne-based pigments, and the like may be mentioned. These pigments or dyes can be used by mixing as appropriate in order to adjust to the intended light transmittance.

The added amount of the coloring agent in the resin film may be adjusted as appropriate so that the above light transmittance of the adhesive sheet 2 is in the range mentioned earlier, but is usually preferably from 0.001 to 2% by mass, more preferably from 0.01 to 1.5% by mass, and still more preferably from 0.1 to 1% by mass.

The base material 21 may contain, in the above resin film, various additives such as flame retardants, plasticizers, antistatic agents, lubricants and fillers.

The thickness of the base material 21 is not particularly limited as long as it can function appropriately in each step where the protective-film forming composite sheet 1 is used and the pores described above are formed by the laser beam irradiation, although it is preferably in the range from 20 to 450 μm, more preferably from 25 to 400 μm, and particularly preferably from 50 to 350 μm.

The fracture elongation of the base material 21 of the adhesive sheet 2 in the present embodiment is preferably equal to or greater than 100% as a value measured at a temperature of 23° C. and a relative humidity of 50%, and particularly preferably from 200 to 1,000%. Here, the fracture elongation is an elongation percentage of the length of the test piece at the time of fracturing the test piece, relative to the original length, in the tensile test conforming to JIS K7161: 1994 (ISO 527-1 1993). The above base material 21 exhibiting the fracture elongation of 100% or more is difficult to break during the expansion step, and it becomes easy to separate the chips formed by cutting the workpiece.

In addition, the tensile stress at 25% strain of the base material 21 of the adhesive sheet 2 in the present embodiment is preferably from 5 to 15 N/10 mm, and the maximum tensile stress is preferably from 15 to 50 MPa. Here, the tensile stress at 25% strain and the maximum tensile stress are measured by the test in accordance with JIS K7161: 1994. If the tensile stress at 25% strain is equal to or greater than 5 N/10 mm and the maximum tensile stress is equal to or greater than 15 MPa, when the workpiece is fixed to a frame, such as a ring frame, after being attached to a dicing sheet 1, the occurrence of loosening of the base material 2 is suppressed, which makes it possible to prevent a transport error from occurring. On the other hand, if the tensile stress at 25% strain is equal to or less than 15 N/10 mm and the maximum tensile stress is equal to or less than 50 MPa, it is possible to suppress detachment of the dicing sheet 1 itself from the ring frame at the time of the expansion step, or the like. It should be noted that the fracture elongation, the tension stress at 25% strain and the maximum tensile stress described above refer to the values measured for the longitudinal direction of the raw sheet in the base material 21.

### 2-2. Adhesive Layer

The adhesive layer 22 provided in the adhesive sheet 2 of the protective-film forming composite sheet 1 according to the present embodiment may be composed of a single layer or may be composed of a multilayer of two or more layers. Even in the case of a single layer or in the case of a multilayer, at least the portion in the adhesive layer 22 which comes into contact with the protective-film forming film 3 is preferably constituted of a material obtained by curing an energy ray-curable adhesive. In addition, in the case of a multilayer, the layer which is in contact with the protective-film forming film 3 (contact layer) is preferably constituted of a material obtained by curing an energy ray-curable adhesive.

Since the material obtained by curing an energy ray-curable adhesive typically exhibits high elastic modulus and also has high surface smoothness, when a protective film is formed by curing the protective-film forming film 3 which is in contact with the cured portion composed of such materials, the surface of the protective film which is in contact with the cured portion exhibits an increase in smoothness. As a result, the gloss becomes higher and the aesthetic appearance as a protective film for chips becomes excellent. In addition, when laser printing is performed on a protective film with high surface gloss, the visibility of the printing is improved.

In those cases where the adhesive layer 22 is composed of a multilayer and the above contact layer is composed of a material obtained by curing an energy ray-curable adhesive, it is preferable that, together with the protective-film forming film 3, the above contact layer is formed so as to be smaller in the surface direction than the layers in the adhesive layer 22 other than the contact layer. An example of such an embodiment is shown in FIG. 2.

In a protective-film forming composite sheet 1A according to the embodiment shown in FIG. 2, the adhesive layer 22 includes a first adhesive layer 221 which is in contact with and laminated on the base material 21, and a second adhesive layer 222 (corresponding to the above contact layer) laminated on the side opposite to the base material 21 side in the first adhesive layer 221. The first adhesive layer 221 is formed so as to have the same size as that of the base material 21. On the other hand, the second adhesive layer 222 is formed as large as the protective-film forming film 3, and is formed so as to be smaller in the surface direction than the first adhesive layer 221 and the base material 21.

In the above configuration, it is possible to adhere a jig such as a ring frame to the portion in the first adhesive layer 221 where the second adhesive layer 222 and the protective-film forming film 3 are not laminated (see FIG. 4). At this time, by making the adhesive force of the first adhesive layer 221 higher than the adhesive force of the second adhesive layer 222 and the protective-film forming film 3, it is possible to fix the ring frame or the like to the first adhesive layer 221 with a strong force. Therefore, even at the time of expansion step or the like, it becomes possible to prevent the protective-film forming composite sheet 1 from detaching from the ring frame.

It should be noted that in order to adhere the jig such as the ring frame described above, an adhesive layer for a jig may be provided separately. For example, in a protective-film forming composite sheet 1B shown in FIG. 3, on the adhesive layer 22 of the adhesive sheet 2 which is the same as in the protective-film forming composite sheet 1, the protective-film forming film 3 having the same size as the adhesive sheet 2 is laminated, and in a peripheral portion in the protective-film forming film 3 on the opposite side of the adhesive sheet 2, a jig adhesive layer 5 for adhering a jig such as a ring frame is provided.

The energy ray-curable adhesive constituting (a portion of) the adhesive layer 22 or the second adhesive layer 222 may be composed mainly of a polymer having energy ray curability, or may be one composed mainly of a mixture of a polymer that is not energy ray-curable and an energy ray-curable polyfunctional monomer and/or oligomer.

A case where the energy ray-curable adhesive includes a polymer having energy ray curability as a main component will be described below.

The polymer having energy ray curability is preferably a (meth)acrylate (co)polymer (A) (hereinafter, may be referred to as an “energy ray-curable polymer (A)”) to which a functional group having energy ray curability (energy ray-curable group) has been introduced in the side chain. The energy ray-curable polymer (A) is preferably obtained by reacting a (meth)acrylic copolymer (a1) having a functional group-containing monomer unit with an unsaturated group-containing compound (a2) having a substituent that binds to the functional group.

The acrylic copolymer (a1) is composed of a structural unit derived from the functional group-containing monomer, and a structural unit derived from a (meth)acrylic acid ester monomer or derivative thereof

The functional group-containing monomer serving as a structural unit of the acrylic copolymer (a1) is preferably a monomer having a polymerizable double bond and a functional group such as a hydroxyl group, an amino group, a substituted amino group, and an epoxy group in the molecule.

More specific examples of the functional group-containing monomers described above include 2-hydroxyethyl (meth)acrylate, 2-hydroxypropyl (meth)acrylate, 3-hydroxypropyl (meth)acrylate and 4-hydroxybutyl (meth)acrylate, and these are used either alone or in combination of two or more types thereof.

As a (meth)acrylic acid ester monomer constituting the acrylic copolymer (a1), an alkyl (meth)acrylate with an alkyl group having 1 to 20 carbon atoms, a cycloalkyl (meth)acrylate or a benzyl (meth)acrylate is used. Among these, an alkyl (meth)acrylate with an alkyl group having 1 to 18 carbon atoms such as methyl (meth)acrylate, ethyl (meth)acrylate, propyl (meth)acrylate, n-butyl (meth)acrylate, 2-ethylhexyl (meth)acrylate, or the like is used particularly preferably.

The acrylic copolymer (a1) is formed to include a structural unit derived from the functional group-containing monomer described above usually in a proportion of 3 to 100% by mass, preferably from 5 to 40% by mass, and a structural unit derived from a (meth)acrylic acid ester monomer or derivative thereof usually in a proportion of 0 to 97% by mass, preferably from 60 to 95% by mass.

Although the acrylic copolymer (a1) can be obtained by copolymerizing a functional group-containing monomer as described above with a (meth)acrylic acid ester monomer or derivative thereof in a conventional manner, dimethylacrylamide, vinyl formate, vinyl acetate, styrene, or the like may be copolymerized in addition to these monomers.

By reacting the acrylic copolymer (a1) having the functional group-containing monomer unit described above with the unsaturated group-containing compound (a2) having a substituent that binds to the functional group, the energy ray-curable polymer (A) can be obtained.

The substituent included in the unsaturated group-containing compound (a2) can be selected as appropriate in accordance with the type of the functional group of the functional group-containing monomer unit included in the acrylic copolymer (a1). For example, when the functional group is a hydroxyl group, an amino group or a substituted amino group, the substituent is preferably an isocyanate group or an epoxy group, and when the functional group is an epoxy group, the substituent is preferably an amino group, a carboxyl group or an aziridinyl group.

In addition, the unsaturated group-containing compound (a2) contains 1 to 5 and preferably 1 to 2 energy ray-polymerizable carbon-carbon double bonds are contained per molecule. Specific examples of such unsaturated group-containing compounds (a2) include, for example, 2-methacryloyloxyethyl isocyanate, meta-isopropenyl-α,α-dimethylbenzyl isocyanate, methacryloyl isocyanate, allyl isocyanate, and 1,1-(bisacryloyloxymethyl)ethyl isocyanate; an acryloyl monoisocyanate compound obtained by the reaction of a diisocyanate compound or polyisocyanate compound and hydroxyethyl (meth)acrylate; an acryloyl monoisocyanate compound obtained by the reaction of a diisocyanate compound or polyisocyanate compound, a polyol compound and hydroxyethyl (meth)acrylate; glycidyl (meth)acrylate; (meth)acrylic acid, 2-(1-aziridinyl)ethyl (meth)acrylate, 2-vinyl-2-oxazoline, 2-isopropenyl-2-oxazoline, and the like.

The unsaturated group-containing compound (a2) is used usually in a proportion of 10 to 100 equivalents, and preferably 20 to 95 equivalents, per 100 equivalents of the functional group-containing monomer of the acrylic copolymer (a1) described above.

In the reaction between the acrylic copolymer (a1) and the unsaturated group-containing compound (a2), depending on the combinations of the functional groups and the substituents, the temperature, pressure, solvent and time of the reaction, the presence or absence of a catalyst, and the type of the catalyst can be appropriately selected. As a result, the functional group present in the acrylic copolymer (a1) reacts with the substituent in the unsaturated group-containing compound (a2), and the unsaturated group is introduced into a side chain in the acrylic copolymer (a1) to obtain the energy ray-curable polymer (A).

The weight average molecular weight of the energy ray-curable polymer (A) obtained in this manner is preferably equal to or more than 10,000, more preferably from 150,000 to 1,500,000, and still more preferably from 200,000 to 1,000,000. It should be noted that the weight average molecular weight (Mw) in the present description is a value in terms of polystyrene as measured by a gel permeation chromatography method (GPC method).

Even when the energy ray-curable adhesive is composed mainly of a polymer having energy ray-curability, the energy ray-curable adhesive may further contain an energy ray-curable monomer and/or oligomer (B).

As the energy ray-curable monomer and/or oligomer (B), for example, it is possible to use an ester of a polyhydric alcohol and (meth)acrylic acid, or the like.

Examples of the energy ray-curable monomer and/or oligomer (B) include monofunctional acrylic acid esters such as cyclohexyl (meth)acrylate and isobornyl (meth)acrylate, polyfunctional acrylic acid esters such as trimethylolpropane tri(meth)acrylate, pentaerythritol tri(meth)acrylate, pentaerythritol tetra(meth)acrylate, dipentaerythritol hexa(meth)acrylate, 1,4-butanediol di(meth)acrylate, 1,6-hexanediol di(meth)acrylate, polyethylene glycol di(meth)acrylate and dimethylol tricyclodecane di(meth)acrylate, polyester oligo(meth)acrylates, and polyurethane oligo(meth)acrylates.

When blending the energy ray-curable monomer and/or oligomer (B), the content of the energy ray-curable monomer and/or oligomer (B) in the energy ray-curable adhesive is preferably from 5 to 80% by mass, particularly preferably from 20 to 60% by mass.

Here, in the case of using ultraviolet rays as the energy rays for curing the energy ray-curable resin composition, it is preferable to add a photopolymerization initiator (C), and by the use of the photopolymerization initiator (C), it is possible to reduce the polymerization curing time and the amount of light irradiation.

Specific examples of the photopolymerization initiators (C) include benzophenone, acetophenone, benzoin, benzoin methyl ether, benzoin ethyl ether, benzoin isopropyl ether, benzoin isobutyl ether, benzoin benzoate, methyl benzoin benzoate, benzoin dimethyl ketal, 2,4-diethylthioxanthone, 1-hydroxy cyclohexyl phenyl ketone, benzyl diphenyl sulfide, tetramethylthiuram monosulfide, azobisisobutyronitrile, benzyl, dibenzyl, diacetyl, β-chloroanthraquinone, (2,4,6-trimethylbenzyl diphenyl)phosphine oxide, 2-benzothiazole-N,N-diethyldithiocarbamate, oligo{2-hydroxy-2-methyl-1-[4-(1-propenyl)phenyl]propanone}, and 2,2-dimethoxy-1,2-diphenylethan-1-one. These may be used alone, or two or more types thereof may be used in combination.

The photopolymerization initiator (C) is preferably used in an amount within a range of 0.1 to 10 parts by mass, and particularly preferably from 0.5 to 6 parts by mass, with respect to 100 parts by mass of the energy ray-curable copolymer (A) (in the case of including the energy ray-curable monomer and/or oligomer (B), with respect to 100 parts by mass of the total amount of the energy ray-curable copolymer (A) and the energy ray-curable monomer and/or oligomer (B)).

In the energy ray-curable adhesive, other components may be included as appropriate, in addition to the components described above. Examples of other components include a polymer component or oligomer component (D) that is not energy ray-curable, and a crosslinking agent (E).

Examples of the polymer component or oligomer component (D) that is not energy ray-curable include polyacrylic esters, polyesters, polyurethanes, polycarbonates and polyolefins, and a polymer or oligomer having a weight average molecular weight (Mw) of 3,000 to 2,500,000 is preferred.

As the crosslinking agent (E), a polyfunctional compound that will react with a functional group included in the energy ray-curable copolymer (A) or the like can be used. Examples of such polyfunctional compounds include isocyanate compounds, epoxy compounds, amine compounds, melamine compounds, aziridine compounds, hydrazine compounds, aldehyde compounds, oxazoline compounds, metal alkoxide compounds, metal chelate compounds, metal salts, ammonium salts, and reactive phenol resins.

By including these other components (D) and (E) in the energy ray-curable adhesive, the tackiness and releasability before curing, the strength after curing, the adhesiveness to other layers, the storage stability and so on may be improved. The added amounts of these other components are not particularly limited, and are appropriately determined within a range of 0 to 40 parts by mass with respect to 100 parts by mass of the energy ray-curable copolymer (A).

Next, a case where the energy ray-curable adhesive is composed mainly of a mixture of a polymer that is not energy ray-curable and an energy ray-curable polyfunctional monomer and/or oligomer will be described below.

As the polymer component that is not energy ray-curable, for example, the same components as those in the acrylic copolymer (a1) described earlier can be used. The content of the polymer component that is not energy ray-curable in the energy ray-curable resin composition is preferably from 20 to 99.9% by mass, and particularly preferably from 30 to 80% by mass.

As the energy ray-curable polyfunctional monomer and/or oligomer, the same as the component (B) described earlier is selected. The mixing ratio between the polymer component that is not energy ray-curable and the energy ray-curable polyfunctional monomer and/or oligomer is preferably from 10 to 150 parts by mass, and particularly preferably from 25 to 100 parts by mass, of the polyfunctional monomer and/or oligomer, with respect to 100 parts by mass of the polymer component.

Also in this case, as described above, the photopolymerization initiator (C) and the crosslinking agent (E) can be included as appropriate.

From the viewpoint of the adhesive force to a jig such as a ring frame, the portion which does not come into contact with the protective-film forming film 3 in the adhesive layer 22 may be composed of a non-energy ray-curable adhesive, or may be composed of the same energy ray-curable adhesive as in the portion contacting the protective-film forming film 3 which is not yet cured, for the sake of unification of materials. In addition, from the viewpoint of the adhesive force to a jig such as a ring frame, the layer which does not come into contact with the protective-film forming film 3 (first adhesive layer 221) is preferably composed of a non-energy ray-curable adhesive. The jig adhesive layer 5 is also preferably composed of a non-energy ray-curable adhesive, in view of the adhesive force to a jig such as a ring frame.

As the non-energy ray-curable adhesive, one having the desired adhesive force and removability is preferred, and it is possible to use, for example, acrylic adhesives, rubber-based adhesives, silicone-based adhesives, urethane-based adhesives, polyester-based adhesives, polyvinyl ether-based adhesives, or the like.

Here, in order to provide the light transmittance as described earlier to the adhesive sheet 2, it is also possible to color the adhesive layer 22. If the adhesive layer 22 is composed of a multilayer, all of the layers may be colored, or a portion of the layers may be colored. When coloring the adhesive layer 22, the adhesive layer 22 preferably contains a coloring agent. As the coloring agent, it is possible to use known agents that are described for the base material 21, although it is preferable to use an organic dye or an organic pigment, and it is particularly preferable to use an organic dye, in view of the formation of pores by the laser beam irradiation, the adhesive force, and the like.

The added amount of the coloring agent in the adhesive layer 22 may be adjusted as appropriate so that the above light transmittance of the adhesive sheet 2 is in the range mentioned earlier, but is usually preferably from 0.001 to 2% by mass, more preferably from 0.01 to 1.5% by mass, and still more preferably from 0.1 to 1% by mass.

The thickness of the adhesive layer 22 is not particularly limited as long as it can function appropriately in each step where the protective-film forming composite sheet 1 is used and the pores described above are formed by the laser beam irradiation. More specifically, it is preferably from 1 to 50 μm, more preferably from 2 to 30 μm, and still more preferably from 3 to 20 μm. In addition, in those cases where the adhesive layer 22 is composed of the first adhesive layer 221 and the second adhesive layer 222 as described above, the thicknesses of the first adhesive layer 221 and the second adhesive layer 222 are each preferably from 1 to 50 μm, more preferably from 2 to 30 μm, and still more preferably from 3 to 20 μm.

On the other hand, the thickness of the jig adhesive layer 5 is preferably from 5 to 200 μm, and particularly preferably from 10 to 100 μm, from the viewpoint of the adhesiveness to a jig such as a ring frame.

### 3. Protective-Film Forming Film

The protective-film forming film 3 is preferably composed of a curable adhesive which is not yet cured. In this case, by curing the protective-film forming film 3 after superposing a workpiece such as a semiconductor wafer to the protective-film forming film 3, it is possible to firmly adhere a protective film to the workpiece, so that a protective film having durability can be formed on a chip or the like. In addition, after curing the curable adhesive, it is possible to perform printing satisfactorily by the laser beam irradiation.

It should be noted that in the case where the protective-film forming film 3 is composed of an uncured curable adhesive, the light transmittance of the protective-film forming film 3 hardly changes even before and after curing. Therefore, if the light transmittance of the protective-film forming film 3 prior to curing at a wavelength of 532 nm is equal to or less than 20%, the light transmittance of the protective-film forming film 3 after curing (protective film) at a wavelength of 532 nm is also equal to or less than 20%.

It is preferable that the protective-film forming film 3 either has tackiness at normal temperature, or exhibits tackiness when heated. Thus, when superposing the workpiece such as a semiconductor wafer to the protective-film forming film 3 as described above, they can be adhered to each other. Therefore, the positioning of the protective-film forming film 3 prior to curing can be performed reliably, and the handling of the protective-film forming composite sheet 1 is facilitated.

The curable adhesive constituting the protective-film forming film 3 having characteristics as described above preferably contains a curable component and a binder polymer component. As the curable component, a thermosetting component, an energy ray-curable component, or a mixture thereof can be used, but it is particularly preferable to use a thermosetting component when considering the curing method of the protective-film forming film 3 and the heat resistance after curing.

Examples of the thermosetting component include epoxy resins, phenolic resins, melamine resins, urea resins, polyester resins, urethane resins, acrylic resins, polyimide resins, benzoxazine resins, and the like, and mixtures thereof. Among these, epoxy resins, phenolic resins and mixtures thereof are preferably used.

Epoxy resins have a property of forming a three-dimensional network when heated to form a solid coating film. As the epoxy resin, various known epoxy resins have been conventionally used, although those having a molecular weight of about 300 to 2,000 are usually preferred, and those having a molecular weight of 300 to 500 are particularly preferred. Furthermore, an epoxy resin which is in a liquid form in an ordinary state and has a molecular weight of 330 to 400, and an epoxy resin which is solid at normal temperature and has a molecular weight of 400 to 2,500, particularly from 500 to 2,000, are preferably used in the form of a mixture. In addition, the epoxy equivalent of the epoxy resin is preferably from 50 to 5,000 g/eq.

Specific examples of such epoxy resins include glycidyl ethers of phenols, such as bisphenol A, bisphenol F, resorcinol, phenyl novolac and cresol novolac; glycidyl ethers of alcohols, such as butanediol, polyethylene glycol, and polypropylene glycol; glycidyl ethers of carboxylic acids, such as phthalic acid, isophthalic acid, and tetrahydrophthalic acid; glycidyl-type or alkyl glycidyl-type epoxy resins in which the active hydrogen bonded to the nitrogen atom of aniline isocyanurate and the like is substituted with a glycidyl group; and the so-called alicyclic epoxides in which an epoxy moiety is introduced by, for example, oxidizing the carbon-carbon double bond in the molecule, such as vinyl cyclohexane diepoxide, 3,4-epoxycyclohexylmethyl-3,4-dicyclohexanecarboxylate, and 2-(3,4-epoxy)cyclohexyl-5,5-spiro(3,4-epoxy)cyclohexane-m-dioxane. In addition, it is also possible to use an epoxy resin having a biphenyl skeleton, a dicyclohexadiene skeleton, a naphthalene skeleton, or the like.

Of these, bisphenol-based glycidyl type epoxy resins, o-cresol novolac-type epoxy resins and phenol novolac-type epoxy resins are preferably used. One type of these epoxy resins may be used alone or two or more types thereof may be used in combination.

In the case of using an epoxy resin, as an auxiliary agent, it is preferable to use a thermally active latent epoxy resin curing agent concomitantly. The thermally active latent epoxy resin curing agent refers to a type of curing agent that does not react with an epoxy resin at room temperature, is activated by heating to a certain temperature or more, and reacts with the epoxy resin. As a method of activating a thermally active latent epoxy resin curing agent, a method of generating active species (anions and cations) in a chemical reaction by heating; a method in which the curing agent is stably dispersed in the epoxy resin at around room temperature but is dissolved (compatible) in the epoxy resin at high temperatures to thereby initiate a curing reaction; a method in which a molecular sieve-enclosed type of curing agent is eluted at high temperatures to thereby initiate a curing reaction; a method using a microcapsule, or the like is available.

Specific examples of the thermally active latent epoxy resin curing agents include various onium salts, and high-melting-point active hydrogen compounds such as dibasic acid dihydrazide compounds, dicyandiamide, amine adduct curing agents, and imidazole compounds. One type of these thermally active latent epoxy resin curing agents may be used alone, or two or more types thereof may be used in combination. The thermally active latent epoxy resin curing agent as described above is used in a proportion of, with respect to 100 parts by weight of the epoxy resin, preferably from 0.1 to 20 parts by weight, more preferably from 0.2 to 10 parts by weight, and still more preferably from 0.3 to 5 parts by weight.

As the phenolic resins, condensates of phenols and aldehydes such as alkylphenols, polyhydric phenols, naphthol, and the like are used without particular limitations. More specifically, phenol novolac resins, o-cresol novolac resins, p-cresol novolac resins, t-butylphenol novolac resins, dicyclopentadiene cresol resins, polyparavinylphenol resins, bisphenol A type novolac resins, or their modified products and the like are used.

The phenolic hydroxyl groups contained in these phenolic resins can easily cause an addition reaction by heating with an epoxy group of the epoxy resin described above to form a cured product with high impact resistance. For this reason, an epoxy resin and a phenolic resin may be used in combination.

The binder polymer component can provide the protective-film forming film 3 with moderate tackiness, thereby improving the operability of the protective-film forming composite sheet 1. The weight average molecular weight of the binder polymer is usually in the range of 50,000 to 2,000,000, preferably from 100,000 to 1,500,000, and particularly preferably from 200,000 to 1,000,000. When the molecular weight is too low, the film formation of the protective-film forming film 3 becomes insufficient, and when it is too high, the compatibility with other components becomes poor, and the uniform film formation is prevented as a result. As the binder polymer, for example, acrylic polymers, polyester resins, phenoxy resins, urethane resins, silicone resins, rubber-based polymers, and the like are used, and acrylic polymers are particularly preferably used.

Examples of the acrylic polymers include (meth)acrylic acid ester copolymers composed of structural units derived from a (meth)acrylic acid ester monomer and a (meth)acrylic acid derivative. Here, as the (meth)acrylic acid ester monomer, (meth)acrylic acid alkyl esters, preferably with an alkyl group having 1 to 18 carbon atoms, such as methyl (meth)acrylate, ethyl (meth)acrylate, propyl (meth)acrylate, butyl (meth)acrylate, and the like are used. In addition, as the (meth)acrylic acid derivative, for example, (meth)acrylic acid, glycidyl (meth)acrylate, hydroxyethyl (meth)acrylate, and the like can be mentioned.

When a glycidyl group is introduced into the acrylic polymer by using glycidyl methacrylate and the like, among those described above, as structural units, the compatibility with the epoxy resin serving as the thermosetting component as described earlier is improved, and the glass transition temperature (Tg) of the protective-film forming film 3 after curing becomes higher, thereby improving the heat resistance. In addition, when a hydroxyl group is introduced into the acrylic polymer by using hydroxyethyl acrylate and the like, among those described above, as structural units, it is possible to control the adhesion and tackiness to the workpiece.

In the case of using an acrylic polymer as the binder polymer, the weight average molecular weight of the polymer is preferably equal to or more than 100,000, and particularly preferably from 150,000 to 1,000,000. The glass transition temperature of the acrylic polymer is usually equal to or less than 20° C. and preferably from about −70 to 0° C., and the polymer has tackiness at normal temperature (23° C.).

As the mixing ratio between the thermosetting component and the binder polymer component, it is preferable to include the thermosetting component, with respect to 100 parts by weight of the binder polymer component, from 50 to 1,500 parts by weight, more preferably from 70 to 1,000 parts by weight, and still more preferably from 80 to 800 parts by weight. When the thermosetting component and the binder polymer component are mixed in such a ratio, moderate tackiness is achieved before curing, an adhering operation can be performed in a stable manner, and a protective film with superior film strength can be obtained after curing.

The protective-film forming film 3 preferably contains a coloring agent and/or a filler. As a result, by controlling the light transmittance within a desired range, it is possible to allow laser printing with excellent visibility. In addition, when the protective-film forming film 3 contains a filler, it is possible to maintain the hardness of the protective film at a high level after curing, while improving the moisture resistance. Further, the surface gloss of the protective film to be formed can also be adjusted to a desired value. Furthermore, the thermal expansion coefficient of the protective film after curing can be brought close to the thermal expansion coefficient of the semiconductor wafer, as a result of which warpage of a semiconductor wafer during processing can be reduced.

As the coloring agent, it is possible to use known agents that are described for the base material 21, although it is preferable to use a pigment, especially an inorganic pigment, in view of the printing properties by the laser beam irradiation. Among the inorganic pigments, carbon black is particularly preferred. Although carbon black is usually black, since it becomes white by the alteration due to the laser beam irradiation and the contrast difference is increased, visibility of the laser printed portion is highly excellent.

Examples of the fillers include inorganic fillers such as silica including crystalline silica, fused silica and synthetic silica, alumina, and glass balloons. Among them, synthetic silica is preferred, and especially a type of synthetic silica from which an a ray source causing malfunction of the semiconductor device has been removed as much as possible is most suitable. The shape of the filler may be any of spherical, needle-like, and amorphous shapes.

Further, as the filler to be added to the protective-film forming film 3, in addition to the above inorganic fillers, a functional filler may be blended. Examples of the functional fillers include electrically conductive fillers such as gold, silver, copper, nickel, aluminum, stainless steel, carbon, ceramic, and those obtained by coating nickel, aluminum or the like with silver, with an aim to impart electrical conductivity after die bonding; and thermally conductive fillers including metal materials such as gold, silver, copper, nickel, aluminum, stainless steel, silicon, and germanium, alloys thereof, and the like, with an aim to impart thermal conductivity.

The added amounts of the coloring agent and filler in the protective-film forming film 3 may be suitably adjusted, so that printing by laser beam irradiation is made possible, and the above effects of the filler can be achieved. More specifically, the added amount of the coloring agent is usually preferably from 0.001 to 5% by mass, more preferably from 0.01 to 3% by mass, and still more preferably from 0.1 to 2.5% by mass. In addition, the added amount of the filler is usually preferably from 40 to 80% by mass, and particularly preferably from 50 to 70% by mass.

The protective-film forming film 3 may contain a coupling agent. By containing a coupling agent, after curing the protective-film forming film 3, it is possible to improve the adhesive properties and adhesion between the protective film and the workpiece while improving the water resistance (wet heat resistance) without impairing the heat resistance of the protective film. As the coupling agent, a silane coupling agent is preferred because of its versatility, cost merits, and the like.

Examples of the silane coupling agent include γ-glycidoxypropyltrimethoxysilane, γ-glycidoxypropylmethyldiethoxysilane, β-(3,4-epoxycyclohexyl)ethyl trimethoxysilane, γ-(methacryloxypropyl) trimethoxysilane, γ-aminopropyltrimethoxysilane, N-6-(aminoethyl)-γ-aminopropyltrimethoxysilane, N-6-(aminoethyl)-γ-aminopropyl methyl diethoxysilane, N-phenyl-γ-aminopropyltrimethoxysilane, γ-ureidopropyltriethoxysilane, γ-mercaptopropyltrimethoxysilane, γ-mercaptopropylmethyldimethoxysilane, bis(3-triethoxysilylpropyl) tetrasulfane, methyltrimethoxysilane, methyltriethoxysilane, vinyltrimethoxysilane, vinyltriacetoxysilane, and imidazolesilane. One type of these may be used alone or two or more types thereof may be mixed and used.

The protective-film forming film 3 may contain a crosslinking agent such as organic polyvalent isocyanate compounds, organic polyvalent imine compounds and organic metal chelate compounds, in order to adjust the cohesive force prior to curing. In addition, the protective-film forming film 3 may contain an antistatic agent, in order to suppress the static electricity and to improve the chip reliability. Furthermore, the protective-film forming film 3 may contain a flame retardant such as phosphate compounds, bromine compounds and phosphorus-based compounds, in order to increase the flame retardancy of the protective film and to improve the reliability as a package.

The thickness of the protective-film forming film 3 is preferably from 3 to 300 μm, more preferably from 5 to 250 μm, and still more preferably from 7 to 200 μm, in order to effectively bring about the function as a protective film.

Here, in the case of forming a protective film by curing the protective-film forming film 3 while being in contact with the adhesive layer 22 (in particular, the portion obtained by curing the energy ray-curable adhesive) in the adhesive sheet 2, the surface gloss value on the adhesive sheet 2 side in the protective film is preferably equal to or greater than 25, and particularly preferably equal to or greater than 30. It should be noted that the gloss values in the present description are values measured using a glossmeter at a measuring angle of 60° in accordance with JIS Z8741. When the surface gloss value of the protective film formed on a chip is within the above range, excellent aesthetic appearance as well as excellent visibility of the print to be formed by laser printing can be achieved.

### 4. Release Sheet

The release sheet 4 is for protecting the protective-film forming film 3 and the adhesive layer 22 until the protective-film forming composite sheet 1 is used, and may not be necessary. The configuration of the release sheet 4 is optional and, for example, one obtained by subjecting a plastic film to a release treatment using a release agent or the like can be used. Specific examples of the plastic film include polyester films composed of polyethylene terephthalate, polybutylene terephthalate, polyethylene naphthalate, and the like, and polyolefin films composed of polypropylene, polyethylene, and the like. As the release agent, it is possible to use silicone-based agents, fluorine-based agents, long chain alkyl-based agents, and the like, although among these, silicone-based agents which can achieve stable performance at a low cost are preferred. The thickness of the release sheet 4 is not particularly limited, although it is usually from about 20 to 250 μm.

### 5. Method of Producing a Composite Sheet for Forming a Protective Film

The composite sheet for forming a protective film (protective-film forming composite sheet) 1 can be produced, preferably, by preparing a first laminate including the protective-film forming film 3 and a second laminate including the adhesive sheet 2 separately, and then laminating the protective-film forming film 3 and the adhesive sheet 2 by using the first laminate and the second laminate, although the process is not limited thereto.

In order to produce the first laminate, the protective-film forming film 3 is formed on a release surface (the surface having releasability; which is usually a surface subjected to a release treatment, but is not limited thereto) of a first release sheet (release sheet 4 in FIG. 1). More specifically, a coating agent for the protective-film forming film that contains the curable adhesive constituting the protective-film forming film 3, and a solvent according to need, is prepared, and is then coated and dried on the release surface of the first release sheet using a coater such as a roll coater, a knife coater, a roll knife coater, an air knife coater, a die coater, a bar coater, a gravure coater, and a curtain coater, to thereby form the protective-film forming film 3. Then, a release surface of the second release sheet is superimposed on and pressure bonded to the exposed surface of the protective-film forming film 3, to thereby obtain a laminated body (first laminate) in which the protective-film forming film 3 is sandwiched between the two release sheets.

In the first laminate, if desired, the protective-film forming film 3 (and the second release sheet) may be subjected to a half-cutting process to be formed into a desired shape, for example, a circular shape or the like. In this case, excess portions of the protective-film forming film 3 and the second release sheet produced by the half-cutting process may be appropriately removed.

On the other hand, in order to produce the second laminate, a coating agent for the adhesive layer that contains the adhesive constituting the adhesive layer 22 and a solvent according to need is coated and dried on the release surface of the release sheet, to thereby form the adhesive layer 22. Thereafter, the base material 21 is pressure bonded on the exposed surface of the adhesive layer 22 to yield a laminated body (second laminate) which is configured of the adhesive sheet 2 composed of the base material 21 and the adhesive layer 22, and the release sheet.

Here, in those cases where the adhesive layer 22 is composed of an energy ray-curable adhesive, it is preferable to cure the energy ray-curable adhesive by irradiating an energy ray onto at least the portion which comes into contact with the protective-film forming film 3. In addition, in those cases where the adhesive layer 22 is composed of a multilayer, and the layer which comes into contact with the protective-film forming film 3 (contact layer; second adhesive layer 222 in FIG. 2) is composed of an energy ray-curable adhesive, it is preferable to cure the energy ray-curable adhesive by irradiating an energy ray onto the contact layer.

As the energy ray, typically, ultraviolet rays, electron rays, and the like are used. The amount of irradiation of energy rays varies depending on the type of energy rays, although in the case of ultraviolet rays, for example, it is preferably from 50 to 1,000 mJ/cm² in light quantity, and particularly preferably from 100 to 500 mJ/cm². In addition, in the case of electron rays, it is preferably about 10 to 1,000 krad.

By curing the portion or layer that comes into contact with the protective-film forming film 3 as described above, the surface of the protective-film forming film 3 after curing which is in contact with the cured adhesive layer 22 exhibits an increase in smoothness. As a result, the gloss becomes higher and the aesthetic appearance as a protective film for chips becomes excellent. In addition, when laser printing is performed on a protective film with high surface gloss, the visibility of the printing is improved.

When the first laminate and the second laminate are obtained as described above, the second release sheet in the first laminate is detached while separating the release sheet in the second laminate, and the protective-film forming film 3 which is exposed in the first laminate and the adhesive layer 22 of the adhesive sheet 2 which is exposed in the second laminate are superposed and pressure bonded. If desired, the adhesive sheet 2 may be subjected to a half-cutting process to be formed into a desired shape, for example, a circular shape or the like having a larger diameter than the protective-film forming film 3. In this case, excess portions of the adhesive sheet 2 produced by the half-cutting process may be appropriately removed.

In this manner, the protective-film forming composite sheet 1 can be obtained, which is configured of: the adhesive sheet 2 formed by laminating the adhesive layer 22 on the base material 21; the protective-film forming film 3 laminated on the adhesive layer 22 side of the adhesive sheet 2; and the release sheet 4 laminated on the opposite side of the adhesive sheet 2 in the protective-film forming film 3.

It should be noted that although the protective-film forming composite sheet 1A shown in FIG. 2 can be produced basically in the same manner as the protective-film forming composite sheet 1, it is preferable to form the first adhesive layer 221 on the second laminate side described above and to form the second adhesive layer 222 on the first laminate side described above. In other words, it is preferable to form the second adhesive layer 222 on the exposed surface of the protective-film forming film 3, after forming the protective-film forming film 3 in the first laminate. When performing the half-cutting process, it is preferable to subject the protective-film forming film 3 and the second adhesive layer 222 to the half-cutting process simultaneously.

In addition, although the protective-film forming composite sheet 1B shown in FIG. 3 can also be produced basically in the same manner as the protective-film forming composite sheet 1, after separating the release sheet 4, it is preferable to form the jig adhesive layer 5 in a peripheral portion on the other side of the adhesive sheet 2 in the protective-film forming film 3.

### 6. Method of Using the Composite Sheet for Forming a Protective Film

Using the protective-film forming composite sheet 1 according to the present embodiment, a method of producing a chip attached with a protective film from a semiconductor wafer serving as a workpiece will be described below as an example. First, the release sheet 4 of the protective-film forming composite sheet 1 is peeled off to expose the protective-film forming film 3 and the peripheral portions of the adhesive layer 22 of the adhesive sheet 2.

Further, as shown in FIG. 4, the protective-film forming film 3 is attached to a semiconductor wafer 6, while attaching the peripheral portions of the adhesive layer 22 to ring frames 7. When attaching the protective-film forming film 3 onto the semiconductor wafer 6, if desired, the protective-film forming film 3 may be heated to exert tackiness.

Then, the protective-film forming film 3 is cured to form a protective film. When the protective-film forming film 3 is a thermosetting adhesive, the protective-film forming film 3 may be heated for an appropriate time at a predetermined temperature.

When the protective film is formed by the cured protective-film forming film 3 as described above, a laser beam is irradiated onto the protective film through the adhesive sheet 2 to perform laser printing. The laser-beam irradiated portion in the protective film changes color, so as to be subjected to printing. In the present embodiment, as the laser beam, it is preferable to use a laser beam having a wavelength of 532 nm.

In the protective-film forming composite sheet 1 according to the present embodiment, the light transmittance of the adhesive sheet 2 at the wavelength described above is from 75 to 85%, as a result of which the material of the laser-beam irradiated portion in the adhesive sheet 2 is decomposed and evaporated, thereby forming a pore that penetrates the adhesive sheet 2. Therefore, even if a gas is generated from the protective film by laser printing, since the gas is removed through the pore, generation of the gas reservoir between the adhesive sheet 2 and the protective film can be effectively suppressed. In addition, the print formed in the protective film is visually recognized satisfactorily through the adhesive sheet 2. As a result, the visibility of the print formed in the protective film becomes excellent, and the adhesion between the adhesive sheet 2 and the protective film is also secured, so that the detachment of chips from the adhesive sheet 2 during the dicing step to be performed later is suppressed.

Upon completion of the laser printing described above, the semiconductor wafer 6 is subjected to dicing in accordance with a conventional method to obtain a chip having a laser-printed protective film (chip with a protective film). Thereafter, if desired, the adhesive sheet 2 is expanded in the planar direction to pick up the protective film-attached chip from the adhesive sheet 2.

The embodiments described above have been described in order to facilitate the understanding of the present invention and not to limit the present invention. Therefore, the elements disclosed in the above embodiments are deemed to also include all design modifications and equivalents falling within the technical scope of the present invention.

For example, in a peripheral portion on the opposite side of the base material 21 in the adhesive layer 22 of the adhesive sheet 2 of the protective-film forming composite sheet 1 described above, a jig adhesive layer for adhering a jig such as a ring frame 6 may be provided separately.

### EXAMPLES

Hereinafter, the present invention will be described in more detail using examples and the like, although the scope of the present invention is not limited to these examples and the like.

### Example 1

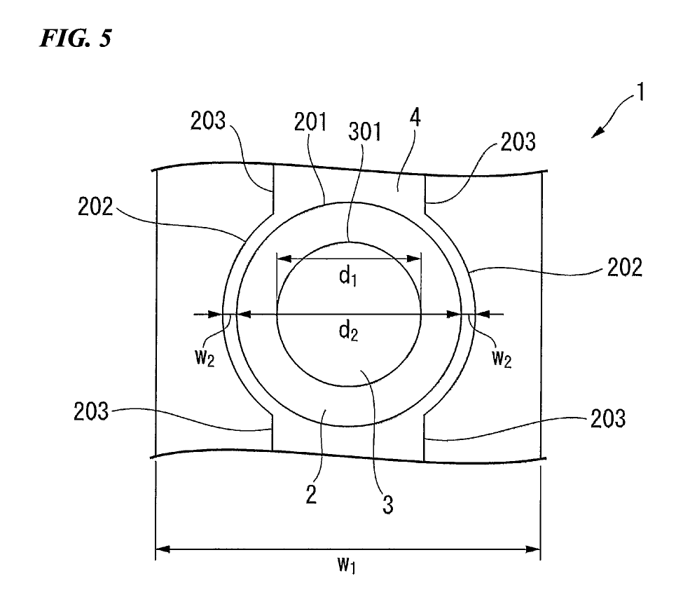

In Example 1, a composite sheet 1 for forming a protective film (protective-film forming composite sheet 1) as shown in FIGS. 1 and 5 was produced as described below.

### (1) Preparation of First Laminate Including Protective-Film Forming Film

The following components (a) to (f) were mixed and diluted with methyl ethyl ketone so that the solid content concentration was 50% by mass, thereby preparing a coating agent for a protective-film forming film.

(a) Binder polymer: (meth)acrylic acid ester copolymer (copolymer obtained by copolymerizing 55 parts by mass of butyl acrylate, 10 parts by mass of methyl acrylate, 15 parts by mass of 2-hydroxyethyl acrylate, and 20 parts by mass of glycidyl methacrylate; weight average molecular weight: 800,000) 17 parts by mass (in terms of solid content, hereinafter, the same applies)
(b) Thermosetting component: mixed epoxy resin (mixture of 60 parts by mass of liquid bisphenol A type epoxy resin (epoxy equivalent: 180 to 200), 10 parts by mass of solid bisphenol A type epoxy resin (epoxy equivalent: 800 to 900), and 30 parts by mass of dicyclopentadiene type epoxy resin (epoxy equivalent: 274 to 286)) 17 parts by mass (c) Curing agent: dicyanamide (ADEKA hardener 3636AS, manufactured by ADEKA CORPORATION) 0.3 parts by mass, and 2-phenyl-4,5-di(hydroxymethyl)imidazole (Curezol 2PHZ, manufactured by SHIKOKU CHEMICALS CORPORATION) 0.3 parts by mass
(d) Coloring agent: carbon black (#MA650, average particle diameter: 28 nm, manufactured by Mitsubishi Chemical Corporation) 2 parts by mass
(e) Silane coupling agent: γ-glycidoxypropyltrimethoxysilane (KBM-403, methoxy equivalent: 12.7 mmol/g, molecular weight: 236.3, manufactured by Shin-Etsu Chemical Co., Ltd.) 0.4 parts by mass
(f) Filler: amorphous silica filler (average particle diameter: 3 μm) 63 parts by mass

A first release sheet (SP-PET381031, manufactured by LINTEC Corporation) which was configured by forming a silicone-based release agent layer on one surface of a polyethylene terephthalate (PET) film having a thickness of 38 μm and a second release sheet (SP-PET381130, manufactured by LINTEC Corporation) which was configured by forming a silicone-based release agent layer on one surface of a PET film having a thickness of 38 μM were prepared.

First, on the release surface of the first release sheet, the coating agent for a protective-film forming film described earlier was applied using a knife coater in such a manner that the thickness of the finally obtained protective-film forming film was 25 μm, and dried to form a protective-film forming film. Then, the release surface of the second release sheet was superposed onto the protective-film forming film to paste the two together, thereby obtaining a laminate composed of the first release sheet (release sheet 4 in FIG. 1), the protective-film forming film (protective-film forming film 3 in FIG. 1) (thickness: 25 μm), and the second release sheet. The laminate was long and was rolled up to form a roll body.

The roll body of the long laminate obtained above was cut into pieces of 300 mm in the width direction (indicated by w1 in FIG. 5). Then, from the second release sheet side, the above laminate was subjected to a half-cutting process in a continuous manner with a circular shape (diameter d1: 220 mm; reference numeral 301 in FIG. 5) in the central portion of the laminate in the width direction, so as to cut the second release sheet and the protective-film forming film. Thereafter, the second release sheet and the protective-film forming film which were present outside the circular shape formed by the half-cutting process were removed. As a result, a first laminate was obtained in which the protective-film forming film having a circular shape was laminated on the release surface of the first release sheet, and the second release sheet having a circular shape was laminated thereon.

### (2) Preparation of Second Laminate Including Adhesive Sheet

The following components (g) and (h) were mixed and diluted with methyl ethyl ketone so that the solid content concentration was 30% by mass, thereby preparing a coating agent for an adhesive layer.

(g) Main adhesive agent: (meth)acrylic acid ester copolymer (copolymer obtained by copolymerizing 40 parts by mass of butyl acrylate, 55 parts by mass of 2-ethylhexyl acrylate, and 5 parts by mass of 2-hydroxylethyl acrylate, weight average molecular weight: 600,000) 100 parts by mass
(h) Crosslinking agent: aromatic polyisocyanate compound (TAKENATE D110N, manufactured by Mitsui Chemicals, Inc.) 10 parts by mass

A release sheet (SP-PET381031, manufactured by LINTEC Corporation) which was configured by forming a silicone-based release agent layer on one surface of a PET film having a thickness of 38 μm, and as the base material, a blue polyvinyl chloride film (manufactured by Okamoto Industries, Inc., thickness: 80 μm) that had been subjected to a corona treatment on one side were prepared.

First, on the release surface of the release sheet, the coating agent for an adhesive layer described earlier was applied using a knife coater in such a manner that the thickness of the finally obtained adhesive layer was 10 μm, and dried to form an adhesive layer. Then, the corona-treated surface of the base material described above was superposed onto the adhesive layer to paste the two together, thereby obtaining a second laminate including the adhesive sheet (adhesive sheet 1 in FIG. 1) composed of the base material (base material 21 in FIG. 1) and the adhesive layer (adhesive layer 22 in FIG. 1) (thickness: 10 μm), and the release sheet. The laminate was long, and was cut into pieces of 300 mm in the width direction (indicated by w1 in FIG. 5), after being rolled up to form a roll body.

### (3) Preparation of a Composite Sheet for Forming a Protective Film

The second release sheet having a circular shape was separated from the first laminate obtained in the above section (1) to expose the protective-film forming film having a circular shape. On the other hand, the release sheet was separated from the second laminate obtained in the above section (2) to expose the adhesive layer. The first laminate and the second laminate were pasted together so that the protective-film forming film described above was brought into contact with the adhesive layer, thereby obtaining a third laminate formed by laminating the adhesive sheet composed of the base material and the adhesive layer, the protective-film forming film, and the first release sheet.

Then, the third laminate was subjected to a half-cutting process from the above base material side, so as to cut the adhesive sheet (the base material and the adhesive layer). More specifically, as shown in FIG. 5, a concentric circular shape (diameter d2: 270 mm; reference numeral 201 in FIG. 5) (circular adhesive sheet) larger than the above protective-film forming film having a circular shape (diameter d1: 220 mm) was formed, while forming an arc (reference numeral 202 in FIG. 5) outside the circular shape with a distance of 20 mm therefrom (indicated by w2 in FIG. 5). In addition, between the circular shapes that were adjacent to each other, two straight lines (reference numeral 203 in FIG. 5) parallel to the widthwise end portion of the third laminate were formed, thereby connecting the adjacent arcs described above by the straight lines.

Thereafter, the portion between the above circular adhesive sheet and the above arc and the portion sandwiched between the above two straight lines were removed to obtain a protective-film forming composite sheet shown in FIGS. 1 and 5.

### Example 2

A protective-film forming composite sheet was produced in the same manner as in Example 1, with the exception that a blue PET/polyethylene composite film (manufactured by Asia Aluminum Co., Ltd., thickness: 100 μm) was used as the base material.

### Example 3

In Example 3, a protective-film forming composite sheet 1A as shown in FIGS. 2 and 5 was produced as described below.

### (1) Preparation of First Laminate Including Protective-Film Forming Film

The following components (i) and (j) were mixed and diluted with methyl ethyl ketone so that the solid content concentration was 50% by mass, thereby preparing a coating agent for a second adhesive layer.

(i) Main adhesive agent: energy ray-curable acrylic copolymer (copolymer obtained by reacting 21.4 parts by mass (so that the isocyanate group of 2-methacryloyloxyethyl isocyanate with respect to the hydroxyl group of 2-hydroxylethyl acrylate was 80 mol %) of 2-methacryloyloxyethyl isocyanate with one which was obtained by copolymerizing 80 parts by mass of 2-ethylhexyl acrylate and 20 parts by mass of 2-hydroxylethyl acrylate, weight average molecular weight: 600,000) 100 parts by mass
(j) Crosslinking agent: aromatic polyisocyanate compound (BHS8515, manufactured by Toyokemu Co., Ltd.) 0.5 parts by mass

A protective-film forming film was formed on the release surface of the first release sheet in the same manner as in Example 1. On the other hand, on the release surface of the second release sheet, the coating agent for a second adhesive layer described earlier was applied using a knife coater in such a manner that the thickness of the finally obtained second adhesive layer was 10 μm, and dried to form a second adhesive layer. Then, the above protective-film forming film and the second adhesive layer were pasted together, thereby obtaining a laminate composed of the first release sheet (release sheet 4 in FIG. 2), the protective-film forming film (protective-film forming film 3 in FIG. 2) (thickness: 25 μm), the second adhesive layer (second adhesive layer 222 in FIG. 2) (thickness: 10 μm), and the second release sheet.

Then, the resultant was cut and subjected to a half-cutting process in the same manner as in Example 1, thereby obtaining a laminate in which the protective-film forming film having a circular shape was laminated on the release surface of the first release sheet, the second adhesive layer having a circular shape was laminated thereon, and the second release sheet having a circular shape was laminated thereon.

Then, the second adhesive layer of the above laminate was irradiated with ultraviolet rays from the second release sheet side (illuminance: 140 mW/cm², light amount: 510 mJ/cm²) to cure the second adhesive layer, and the resultant was used as the first laminate.

### (2) Preparation of Second Laminate Including Portion of Adhesive Sheet

In the same manner as in Example 1, the first adhesive layer was formed on the release surface of the release sheet, and after laminating the base material, the resultant was cut, thereby obtaining a second laminate composed of the base material (base material 21 in FIG. 2), the first adhesive layer (adhesive layer 221 in FIG. 2) (thickness: 10 μm), and the release sheet.

### (3) Preparation of a Composite Sheet for Forming a Protective Film

The second release sheet having a circular shape was separated from the first laminate obtained in the above section (1) to expose the second adhesive layer. On the other hand, the release sheet was separated from the second laminate obtained in the above section (2) to expose the first adhesive layer. The first laminate and the second laminate were pasted together so that the second adhesive layer described above was brought into contact with the first adhesive layer, thereby obtaining a third laminate formed by laminating the adhesive sheet composed of the base material, the first adhesive layer and the second adhesive layer, the protective-film forming film, and the first release sheet.

Then, the resultant was subjected to a half-cutting process in the same manner as in Example 1, thereby obtaining a protective-film forming composite sheet as shown in FIGS. 2 and 5.

### Example 4

A protective-film forming composite sheet was produced in the same manner as in Example 1, with the exception that a light blue polypropylene film (manufactured by Mitsubishi Plastics, Inc., thickness: 80 μm) was used as the base material.

### Comparative Example 1

A protective-film forming composite sheet was produced in the same manner as in Example 1, with the exception that a colorless polyolefin film (manufactured by Mitsubishi Plastics, Inc., thickness: 80 μm) was used as the base material.

### Comparative Example 2

A protective-film forming composite sheet was produced in the same manner as in Example 1, with the exception that a pale black polyvinyl chloride film (manufactured by Okamoto Industries, Inc., thickness: 50 μm) was used as the base material.

### Comparative Example 3

A protective-film forming composite sheet was produced in the same manner as in Example 1, with the exception that a deep black polyvinyl chloride film (manufactured by Okamoto Industries, Inc., thickness: 100 μm) was used as the base material.

### Comparative Example 4

A protective-film forming composite sheet was produced in the same manner as in Example 1, with the exception that a colorless polyolefin film (manufactured by Mitsubishi Plastics, Inc., thickness: 80 μm) was used as the base material, and after cutting a laminate including an adhesive sheet, a through hole (through hole diameter: 50 μm, gap: 5.0 mm) was formed in the adhesive sheet using a CO₂ gas laser (manufactured by Panasonic Corporation, YS-HCS03T04, Wavelength: 10.6 μm).

### Test Example 1

### Measurement of Light Transmittance

Regarding each adhesive sheets of Examples and Comparative Examples, a spectrophotometer (UV-VIS-NIR SPECTROPHOTOMETER UV-3600, manufactured by SHIMADZU CORPORATION) was used to measure the transmittance of light in the wavelength range of 300 to 1,200 nm. From the obtained measurement results, the light transmittance at a wavelength of 532 nm was calculated. For the measurement, a large sample chamber MPC-3100 that was included in the spectrophotometer was used, and an integrating sphere built in the spectrophotometer was used.

In addition, each protective-film forming films of Examples and Comparative Examples was also subjected to the measurement in the same manner to calculate the light transmittance at a wavelength of 532 nm. Furthermore, as a reference example, a dicing tape (Adwill D-676, manufactured by Lintec Corporation) was also subjected to the measurement in the same manner to calculate the light transmittance at a wavelength of 532 nm. The results are shown in Table 1.

### Test Example 2

### Measurement of Gross Value of Protective Film

Using a tape mounter device (RAD2700, manufactured by Lintec Corporation), the protective-film forming film which was exposed by separating the first release sheet from the protective-film forming composite sheets of Examples and Comparative Examples was adhered to #2000 polished surface of a silicon wafer (diameter: 8 inches, thickness: 350 μm) while being heated to 70° C. At the same time, the exposed adhesive layer or the first adhesive layer was adhered to the ring frame. Then, by heating at 130° C. for 2 hours, the protective-film forming film was cured to form a protective film on the silicon wafer.

The adhesive sheet was peeled off from the obtained protective film-attached wafer, and the specular gloss at 60° was measured for the exposed surface of the protective film (surface opposite to the silicon wafer) in accordance with JIS Z8741 using a glossmeter (VG2000, manufactured by Nippon Denshoku Industries Co., Ltd.). The resulting value was used as the gloss value of the protective film. The results are shown in Table 2.

### Test Example 3

### Evaluation of Gas Reservoir

A laminate of the adhesive sheet and the protective film-attached wafer which was fixed to the ring frame was obtained in the same manner as in Test Example 2. Then, using a printing apparatus (MD-T1000, manufactured by KEYENCE Corporation, wavelength used: 532 nm), laser printing (character size: 0.5 mm×0.5 mm, character spacing: 0.3 mm, number of characters: 20 characters) was carried out on the protective film by irradiating a laser beam having a wavelength of 532 nm from the adhesive sheet side, respectively.

Whether the gas reservoir was generated by laser printing at the interface between the protective film-attached wafer and the adhesive sheet in the above laminate was evaluated by visual observation based on the criteria shown below. The results are shown in Table 2.

### =Evaluation of Gas Reservoir=

A: Gas reservoir was not generated in all the characters.

B: Gas reservoir was partially generated.

C: Gas reservoir was generated in all the characters.

### Test Example 4

### Evaluation of Character Visibility/Laser Printing Properties

The visibility through the adhesive sheet of the laser printed characters formed on the protective film in Test Example 3 was evaluated by visual observation based on the criteria shown below. In addition, the laser printing properties were evaluated as “o” if both the gas reservoir generation and the character visibility were rated as “A”, and the laser printing properties were evaluated as “x” if either one of them was rated other than “A”. The results are shown in Table 2.

### =Evaluation of Character Visibility=

A: It was possible to read all the characters without any problems.

B: It was possible to read all the characters, although there were some unclear parts.

C: There was (a) partially unreadable character(s).

D: All or most of the characters were unreadable.

TABLE 1

| | Light transmittance | Light transmittance of |
|---|---|---|
| | of adhesive | protective-film |
| | sheet [%] | forming film [%] |
| Example 1 | 79 | 0 |
| Example 2 | 82 | 0 |
| Example 3 | 77 | 0 |
| Example 4 | 75 | 0 |
| Comparative Example 1 | 88 | 0 |
| Comparative Example 2 | 35 | 0 |
| Comparative Example 3 | 2 | 0 |
| Comparative Example 4 | 88 | 0 |
| Reference Example | 91 | — |

TABLE 2

| | Gloss | Gas | Character | Laser printing |
|---|---|---|---|---|
| | value | reservoir | visibility | properties |
| Example 1 | 2 | A | A | ∘ |
| Example 2 | 2 | A | A | ∘ |
| Example 3 | 45 | A | A | ∘ |
| Example 4 | 2 | A | A | ∘ |
| Comparative Example 1 | 2 | C | D | x |
| Comparative Example 2 | 2 | A | B | x |
| Comparative Example 3 | 2 | A | D | x |
| Comparative Example 4 | 2 | B | C | x |

As is apparent from Table 1 and Table 2, when the light transmittance was measured using an integrating sphere, in the protective-film forming composite sheets of Examples in which the light transmittance of the adhesive sheet at a wavelength of 532 nm was within the range of 75 to 85%, there was no generation of gas reservoir, and the character visibility through the adhesive sheet was also high, resulting in superior laser printing properties.

In contrast, in the protective-film forming composite sheet of Comparative Example 1, no pore was formed in the adhesive sheet, thereby generating a gas reservoir. In addition, in the protective-film forming composite sheet of Comparative Example 2, although a pore was formed in the adhesive sheet, the character visibility through the adhesive sheet was not satisfactory. On the other hand, in the protective-film forming composite sheet of Comparative Example 3, the laser beam was absorbed in the adhesive sheet, and the printing could not be performed on the protective film. In addition, in the protective-film forming composite sheet of Comparative Example 4, a gas reservoir was generated so that it was impossible to read the text except for the characters in the vicinity of the through hole that was formed in advance in the adhesive sheet.

### INDUSTRIAL APPLICABILITY

The protective-film forming composite sheet according to the present invention is suitably used for producing a chip with a laser-printed, protective film from a semiconductor wafer.

### REFERENCE SIGNS LIST

1, 1A, 1B: Protective-film forming composite sheet
2: Adhesive sheet
21: Base material
22, 221, 222: Adhesive layer
201: Circular shape
202: Arc
203: Straight line
3: Protective-film forming film
301: Circular shape
4: Release sheet
5: Jig adhesive layer
6: Semiconductor wafer

1. A composite sheet for forming a protective film, the composite sheet comprising:
an adhesive sheet obtained by laminating an adhesive layer on one surface of a base material; and
a protective-film forming film laminated on said adhesive layer side of said adhesive sheet,
wherein said adhesive sheet does not have a through hole penetrating the adhesive sheet in a thickness direction, and
light transmittance of said adhesive sheet at a wavelength of 532 nm measured using an integrating sphere is from 75 to 85%.

2. The composite sheet for forming a protective film according to claim 1,
wherein at least a portion in said adhesive layer which is in contact with said protective-film forming film comprises a material obtained by curing an energy ray-curable adhesive.

3. The composite sheet for forming a protective film according to claim 1, wherein said base material comprises a polypropylene film.

4. The composite sheet for forming a protective film according to claim 1,
wherein said protective-film forming film comprises an uncured curable adhesive, and
a surface gloss value on said adhesive layer side of said protective-film forming film after curing is equal to or more than 25.

5. The composite sheet for forming a protective film according to claim 1,
wherein an object to which said composite sheet for forming a protective film is adhered is a semiconductor wafer, and
said protective-film forming film is a layer for forming a protective film onto said semiconductor wafer or a semiconductor chip obtained by dicing said semiconductor wafer.
